(19) United States
(12) Patent Application Publication
(10) Pub. No.: US 2007/0184666 A1
(43) Pub. Date: Aug. 9, 2007

(54) Method for removing residue containing an embedded metal

(75) Inventors: Patricia Beauregard Smith, Colleyville, TX (US); Heungsoo Park, McKinney, TX (US); Laura M Matz, Murphy, TX (US); Vinay Shah, Colorado Springs, CO (US); Phillip D. Matz, Murphy, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/349,864

(22) Filed: Feb. 8, 2006

(51) Int. Cl. H01L 21/302; H01L 21/31

(52) U.S. Cl. 438/723; 438/787

(57) ABSTRACT

The present invention provides a method for removing residue from a cavity during the formation of an interconnect structure, a method for manufacturing an interconnect structure using the same, and a method for manufacturing an integrated circuit using the same. The method for removing residue from a cavity during the formation of an interconnect structure, among other steps, may include subjecting residue (410) having an embedded metal therein located within a cavity (310) in a dielectric layer (240) and over at least a portion of a conductive feature (220) to a short duration oxidation process so as to oxidize a substantial portion of the embedded metal, and removing the residue (410) containing the oxidized embedded metal using an etch process.

### TECHNICAL FIELD OF THE INVENTION

The present invention is directed, in general, to a method for removing residue, and more specifically to a method for removing residue containing an embedded metal, a method for manufacturing an interconnect and/or integrated circuit using the same.

### BACKGROUND OF THE INVENTION

In the manufacture of semiconductor products such as integrated circuits, individual electrical devices are formed on or in a semiconductor substrate, and are thereafter interconnected to form electrical circuits. Interconnection of these devices within an integrated circuit is typically accomplished by forming a multi-level interconnect network in layers formed over the electrical devices, by which the device active elements are connected to one another to create the desired circuits. Individual wiring layers within the multi-level network are formed by depositing an insulating or dielectric layer over the discrete devices or over a previous interconnect layer, and patterning and etching cavities such as vias and trenches. Conductive material, such as copper is then deposited into the cavities and the wafer is planarized using chemical mechanical polishing (CMP) to form an interconnect structure.

Typical interconnect structures are fabricated using single or dual damascene processes in which trenches and vias are formed (etched) in a dielectric layer. Copper is then deposited into the trenches and vias and over the insulative layer, followed by CMP planarization to leave a copper wiring pattern including the desired interconnect metal inlaid within the dielectric layer trenches. The process may be repeated to form further interconnect layers or levels by which the desired circuit interconnections are made in a multi-level interconnect network.

Etch-stop layers are often formed beneath the dielectric material layers to provide controlled stopping of the via and/or trench formation etch processes. Silicon nitride (SiNₓ) is typically employed as an etch stop material, although recently other materials such as silicon carbide (SiC) and silicon carbonitride (SiCN) layers have also been used for etch-stop layers in interconnect processing. Diffusion barriers are often formed in the damascene cavities prior to deposition of copper to mitigate diffusion of copper into the dielectric material. Such barriers are typically formed using conductive compounds of transition metals such as tantalum nitride, titanium nitride, and tungsten nitride as well as the various transition metals themselves. Conductive metals, such as aluminum, copper, or the like are then used to fill the cavities after barrier layer formation, where copper is gradually replacing aluminum to improve the conductivity of the interconnect circuits.

To reduce or control RC delay times in finished semiconductor products, recent developments have focused on the use of low dielectric constant (low-k) dielectric materials. The low k material is used between the metal wiring lines, in order to reduce the capacitance and consequently to increase the circuit speed. Examples of low-k dielectric materials include spin-on-glasses (SOGs), as well as organic and quasi-organic materials such as organo-silicate-glasses (OSGs), for example, having dielectric constants (k) as low as about 2.6-2.8, and ultra low-k dielectric materials having dielectric constants below 2.6. OSG materials are low density silicate glasses to which alkyl groups have been added to achieve a low-k dielectric characteristic. This class of materials includes, for example, polysilsesquioxanes, such as HSQ (hydrogen silsequioxane), MSQ (methyl silsequioxane), and fluorinated silica glasses (FSGs). Totally organic, non-silicaceous materials such as fluorinated polyarylene ethers, are seeing an increased usage in semiconductor processing technology because of their favorable dielectric characteristics and ease of application.

Single and dual damascene processes using OSG, FSG, or ultra low-k dielectric materials, SiC materials, and copper fill metals can thus be employed to increase speed, reduce cross talk, and reduce power consumption in modern high-speed, high-density devices. However, incorporating these newer materials into workable semiconductor fabrication processes presents additional challenges. Etch processes used to remove the etch-stop material beneath the dielectric layer or layers often leave polymer residue on the dielectric sidewalls and the bottom of the trench or via cavities, which must be cleaned or removed prior to barrier formation and filling.

This residual polymer, if left uncleaned, causes a high resistance interface between underlying conductive features and the deposited fill or barrier material, thus exacerbating RC delays. However, the cleaning process itself must not corrode or damage the underlying conductive feature to which connection is to be made. Further, the cleaning process should not change the dimensions of the cavities. Wet cleaning processes have been used in the past to remove polymers formed on oxide type dielectric sidewalls when etching through SiN type etch-stop layers. However, the recent introduction of OSG and other low-k dielectric materials in combination with SiC etch-stop materials and copper fill materials has rendered previous cleaning processes ineffective in removing the residue.

Thus, there is a need for improved cleaning techniques by which the etch-stop etch residue can be cleaned or removed from the interconnect structure cavities without adversely impacting device dimensions or performance.

### SUMMARY OF THE INVENTION

To address the above-discussed deficiencies of the prior art, the present invention provides a method for removing residue from a cavity during the formation of an interconnect structure, a method for manufacturing an interconnect using the same, and a method for manufacturing an integrated circuit using the same. The method for removing residue from a cavity during the formation of an interconnect structure, among other steps, may include subjecting residue having an embedded metal therein located within a cavity in a dielectric layer and over at least a portion of a conductive feature to a short duration oxidation process so as to oxidize a substantial portion of the embedded metal, and removing the residue containing the oxidized embedded metal using an etch process.

The method for manufacturing an interconnect structure, without limitation, may include forming a cavity in a dielectric layer located over a substrate to expose a portion of an etch-stop layer underlying the dielectric layer, and removing the exposed portion of the etch-stop layer to expose at least a portion of a conductive feature underlying the etch-stop layer, the removing leaving a residue having an embedded metal therein above at least a portion of the conductive feature. The method may further include subjecting the residue having the embedded metal therein to a short duration oxidation process so as to oxidize a substantial portion of the embedded metal, and removing the residue containing the oxidized embedded metal using an etch process.

The method for manufacturing the integrated circuit, without being limited to such, may include: 1) providing a semiconductor substrate having transistor devices located thereover, 2) forming a dielectric layer over the transistor devices, 3) forming an interconnect within the dielectric layer, the interconnect contacting at least one of the transistor devices, the forming of the interconnect including steps similar to the method for manufacturing the integrated circuit in the paragraph directly above.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a flow diagram of one embodiment of a method for manufacturing an interconnect structure in accordance with the principles of the present invention;

FIG. 2 illustrates a cross-sectional view of an interconnect structure at an initial stage of manufacture;

FIG. 3 illustrates a cross-sectional view of the partially completed interconnect structure illustrated in FIG. 2 after forming a cavity in the dielectric layer;

FIG. 4 illustrates a cross-sectional view of the partially completed interconnect structure illustrated in FIG. 3 after removing the exposed portion of the etch-stop layer within the cavity and having removed the photoresist layer;

FIG. 5 illustrates a cross-sectional view of the partially completed interconnect structure illustrated in FIG. 4 after having removed the residue using a unique process conducted in accordance with the principles of the present invention;

FIG. 6 illustrates a cross-sectional view of the partially completed interconnect structure illustrated in FIG. 5 after forming a conventional barrier/adhesion layer within the cavity in the dielectric layer, and forming a blanket layer of conductive material over the metal barrier/adhesion layer and within the cavity;

FIG. 7 illustrates a cross-sectional view of the partially completed interconnect structure illustrated in FIG. 6 after conventionally polishing the blanket layer of conductive material to form a second conductive feature; and

FIG. 8 illustrates a cross-sectional view of an integrated circuit manufactured in accordance with the principles of the present invention.

### DETAILED DESCRIPTION

The present invention is based, at least in part, on the unique acknowledgement that residue that remains after removing an etch-stop layer in an interconnect manufacturing process may contain embedded metal particles therein that retard, if not substantially prevent, standard wet or plasma etch processes from removing the residue. In view of this unique acknowledgement, the present invention recognized that the residue could be subjected to a short duration oxidation process so as to oxidize a substantial portion of the embedded metal, and thereby allow the standard wet etch to easily remove the remaining residue. Short duration oxidation, as used herein, refers to an oxidation that is long enough to oxidize a substantial portion of the embedded metal but short enough to not severely damage the interconnect features located nearby, including without limitation the conductive feature located there under and the sidewalls of the cavity in which the residue is located.

Prior to the aforementioned unique acknowledgement it was generally undesirable to have the features of the interconnect structure come into contact with a source of oxygen. For example, it is well known that exposure to large amounts of oxygen for an extended amount of time will cause conductive features, especially copper conductive features, to substantially oxidize, and thereby increase their resistance. Additionally, the exposure of dielectric layers, such as low dielectric constant (k) dielectric layers (e.g., organo-silicate-glasses (OSGs)), to large amounts of oxygen for an extended amount of time tends to draw the carbon from the dielectric layer. Unfortunately, the lack of carbon makes the sidewalls of the dielectric layer susceptible to critical dimension (CD) degradation during subsequent wet clean steps. Because of these, as well as other problems, it is counter-intuitive to include a source of oxygen into the removal of the residue.

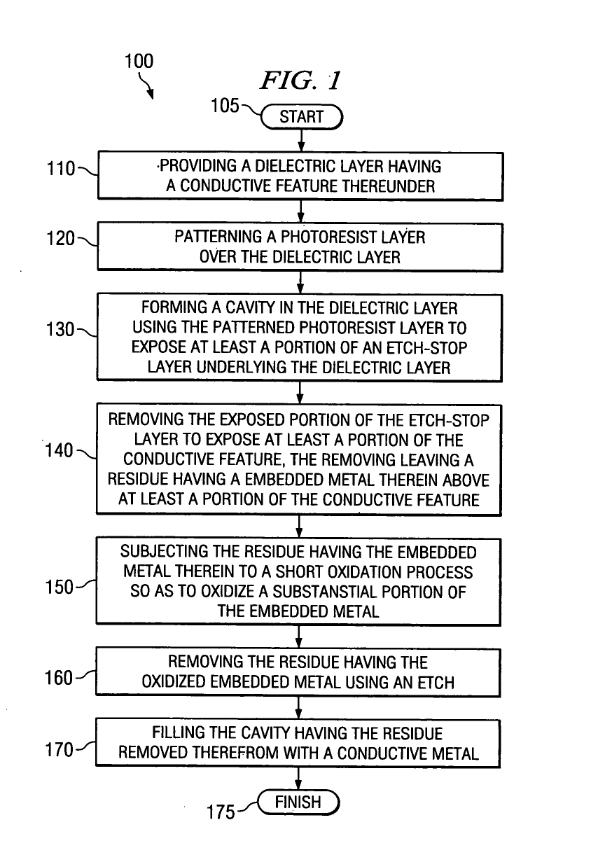

Turning now to FIG. 1, illustrated is a flow chart 100 setting out one embodiment for manufacturing an interconnect structure in accordance with the principles of the present invention. The method for manufacturing the interconnect structure described in the flow chart 100 of FIG. 1 also encompasses a unique method for removing residue from a cavity during the formation of an interconnect structure in accordance with the principles of the present invention. Accordingly, the two methods will be discussed together.

The method for manufacturing an interconnect structure in accordance with the principles of the present invention begins in a start step 105, shown in FIG. 1. Thereafter, in a step 110, a dielectric layer having a conductive feature thereunder is provided. The dielectric layer may comprise a variety of different layers while staying within the scope of the present invention. Nevertheless, in various embodiments of the present invention the dielectric layer comprises a low dielectric constant (k) material. As used herein, a low dielectric constant (k) material is a material having a dielectric constant (k) less than that of silicon dioxide, and thus a dielectric constant (k) of less than about 3.9. In one exemplary embodiment of the present invention the dielectric layer comprises OSG. As previously mentioned, positioned under the dielectric layer is the conductive feature. While the conductive feature may comprise almost any conductive material, certain embodiments of the present invention benefit the most when the conductive feature is a copper containing conductive feature.

After step 110, a photoresist layer is formed and patterned over the dielectric layer in a step 120. The photoresist layer may be any known or hereafter discovered photoresist layer that is in accordance with the principles of the present invention. Additionally, the photoresist layer may be patterned using any conventional process. In an exemplary embodiment, the photoresist layer is conventionally patterned to have an opening therein, the opening being located over the conductive feature.

In a step 130, the patterned photoresist layer is conventionally used to form a cavity in the dielectric layer. For example, the dielectric layer may be subjected to a conventional dielectric layer etch, for example a conventional oxide etch if the dielectric layer is an OSG layer. In this embodiment of the present invention, the step 130 etches down through the dielectric layer, stopping on an etch-stop layer. Thus, the photoresist layer is used to expose at least a portion of the etch-stop layer underlying the dielectric layer. In those embodiments wherein the opening in the patterned photoresist layer is located over the conductive feature, the cavity in the dielectric layer should also be located over the conductive feature.

Thereafter, in a step 140, the exposed portion of the etch-stop layer is removed to expose at least a portion of the conductive feature. The removing of the exposed portion of the etch-stop layer may be accomplished a number of different ways. For instance, when the etch-stop layer comprises silicon nitride or silicon carbide, a standard silicon nitride or silicon carbide etch could be used to remove the exposed portion of the etch-stop layer. Unfortunately, the etch processes used to remove the etch-stop layer beneath the dielectric layer often leave residue (e.g., polymeric residue) on the dielectric sidewalls and the bottom of the trench or via cavities. In accordance with the principles of the present invention, this residue tends to have embedded metal therein.

In a unique step 150, the residue having the embedded metal therein may be subjected to a short duration oxidation process (e.g., using an oxygen containing fluid, such as an oxygen containing gas) so as to oxidize a substantial portion of the embedded metal. In one embodiment of the present invention, the short duration oxidation process is a short duration oxidation plasma process. It is important at this unique step that the short duration oxidation process not severely damage the underlying conductive feature or the sidewalls of the dielectric layer. A variety of different oxidation conditions are sufficient to meet this standard. For example, the oxidation conditions may be tailored as a whole such that the residue is subjected to the oxidation process for a period of time of less than about 60 seconds, with a preferred time range of between about 10 seconds and about 45 seconds, a temperature of less than about 100° C., with an exemplary temperature ranging from about room temperature to about 60° C., a pressure ranging from about 5 mTorr to about 2000 mTorr, and a power ranging from about 300 watts to about 1500 watts. Similarly, a bias ranging from about zero watts to about 75 watts could also be used. Furthermore, in certain advantageous embodiments the oxidation process may also be conducted using from about 5% to about 100% commercially pure oxygen. What advantageously results from step 150 is that a substantial portion of the embedded metal, if not all of the embedded metal, is oxidized.

Thereafter, in a step 160, the residue having the oxidized embedded metal is removed using an etch process. For example, a wet etch process, such as a fluorine-containing wet etch process, could be used to remove the residue. In one exemplary embodiment, the wet etch could be any number of commercially available fluorine-containing solvents. Other etches, cleans, or solvents could nonetheless also be used.

After removing the residue having the oxidized embedded metal in the step 160, a conductive material is placed in the cavity in the dielectric layer to contact the conductive feature and form a functional interconnect structure in the step 170. The process would then terminate in a step 175, or repeat with a new interconnect layer until the desired number of metal levels is produced, such as in a typical multiple-level interconnect structure.

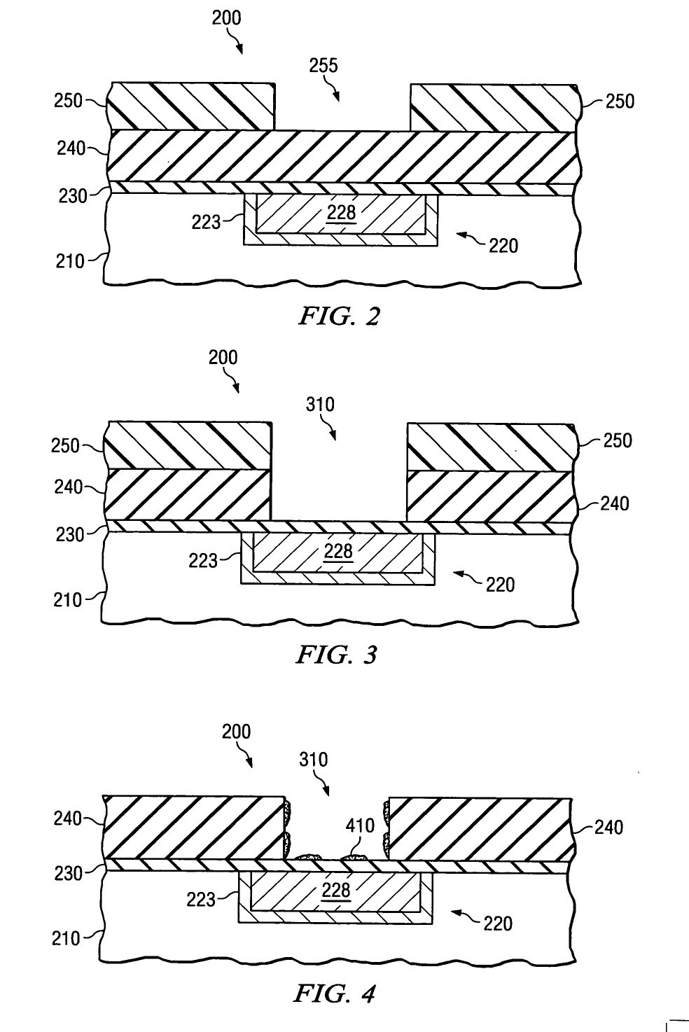

Turning now to FIGS. 2-7, with continued reference to FIG. 1, illustrated are cross-sectional views of detailed manufacturing steps illustrating how one might manufacture an interconnect structure in accordance with the principles of the present invention. While the embodiments illustrated in FIGS. 2-7 are directed to a single damascene interconnect structure, the unique aspects of the present invention are also applicable to dual damascene interconnect structures. FIG. 2 includes a partially completed interconnect structure 200, which initially includes a substrate 210 having a conductive feature 220 located therein or thereunder. The substrate 210 may comprise a variety of different configurations and materials without departing from the inventive aspects of the present invention. For instance, in the embodiment of FIG. 2 the substrate 210 is a low dielectric constant (k) substrate. Suitable low dielectric constant (k) substrates include, among others, OSG, BPSG, PSG, TEOS, aerogel, xerogel, HSQ, MSQ or any other low dielectric constant materials. Nevertheless, the substrate 210 may comprise other non-low dielectric constant (k) substrates and remain within the scope of the present invention.

As previously mentioned, located in or under the substrate is a conductive feature 220. The conductive feature 220 may also comprise a number of different features while remaining within the scope of the present invention. In one aspect of the invention, the conductive feature 220 is a conductive trace, runner or trench traversing along at least a portion of an interlevel dielectric layer. In another aspect, however, the conductive feature 220 is a transistor device level feature, such as a gate electrode or source/drain contact region. Other conductive features 220 may also exist.

The conductive feature 220 illustrated in FIG. 2, however, happens to be a conductive trace, runner or trench. As illustrated, the conductive feature 220 includes a barrier/adhesion layer 223 and a conductive plug 228. The conductive plug 228 is preferably comprised of copper or copper-doped aluminum (preferably on the order of 0.5 to 2.5 wt % of copper in aluminum). Other copper containing conductive plugs 228, or for that matter other general conductive plugs, are within the scope of the present invention. The barrier/adhesion layer 223, among others, may be comprised of titanium, titanium nitride, a Ti/TiN stack, tantalum, tantalum nitride, or other barrier-like materials or mixtures of these materials that adhere well to copper, aluminum and/or the substrate 210.

Located over the substrate 210 and the conductive feature 220 is an etch-stop layer 230. The etch-stop layer 230, in accordance with the principles of the present invention, may comprise silicon nitride, silicon carbide, SiCN or other similar materials, for example. Nevertheless, other types of materials not disclosed herein could be use as the etch-stop layer 230. While the etch-stop layer 230 may comprise various different thicknesses, the exemplary embodiment of FIGS. 2-7 has the etch-stop layer 230 having a thickness ranging from about 75 nm to about 20 nm.

Positioned over the substrate 210 and the conductive feature 220 in the embodiment of FIG. 2 is a dielectric layer 240. In the embodiment of FIG. 2 the dielectric layer 240 is a low dielectric constant (k) dielectric layer. The dielectric layer 240, similar to the embodiment wherein the substrate 210 comprises a low dielectric constant (k) material, may comprise, among others, OSG, BPSG, PSG, aerogel, xerogel, HSQ, MSQ or any other low dielectric constant materials. Other embodiments exist wherein the dielectric layer 240 does not comprise a low dielectric constant (k) material, but rather, an SiO₂ layer such as TEOS.

Positioned over the dielectric layer 240 is a photoresist layer 250. The photoresist layer 250 illustrated in FIG. 2 comprises only a single layer; however, those skilled in the art understand that the photoresist layer 250 could comprise any number of layers while staying within the scope of the present invention. For example, the photoresist layer 250 may consist of multiple layers of different materials, which when used together, enable the patterning of the features of interest. One such embodiment might be where the photoresist layer 250 comprises both a bottom anti-reflection coating (BARC) portion and a photoresist portion. As illustrated in FIG. 2, the photoresist layer 250 has an opening 255 conventionally patterned therein. Those skilled in the art understand the process for forming and patterning the photoresist layer 250, thus no further detail is warranted.

Turning now to FIG. 3, with continued reference to FIG. 1, illustrated is a cross-sectional view of the partially completed interconnect structure 200 illustrated in FIG. 2 after forming a cavity 310 in the dielectric layer 240 using the opening 255 (FIG. 2) in the photoresist layer 250. Preferably, this is accomplished by subjecting the dielectric layer 240 to CF₄, CHF₃, or other fluorinated compound plasma environment, as well as other plasma environments known in the art to etch or remove dielectric materials. Nevertheless, any other known or hereafter discovered process could be used to form the cavity 310. As is illustrated in FIG. 3, the etching of the dielectric layer 240 stops on the etch-stop layer 230.

Turning now to FIG. 4, with continued reference to FIG. 1, illustrated is a cross-sectional view of the partially completed interconnect structure 200 illustrated in FIG. 3 after removing the exposed portion of the etch-stop layer 230 within the cavity 310 and having removed the photoresist layer 250. As is illustrated, the removal of the etch-stop layer 230 exposes at least a portion of the conductive feature 220 underlying the etch-stop layer 230. Those skilled in the art understand that the processes and/or etches that might be used to remove the etch-stop layer 230 depend somewhat on the material composition of the etch-stop layer 230. For example, when the etch-stop layer 230 comprises silicon nitride, silicon carbide or SiCN, a fluorine containing plasma is generally used to remove the exposed etch-stop layer 230. Nevertheless, the present invention should not be limited to such.

In the embodiment illustrated in FIG. 4, after removing the exposed etch-stop layer 230 the patterned photoresist layer 250 may be removed. In one embodiment of the present invention, the photoresist layer 250 is removed using a conventional plasma process. For example, a hydrogen/argon plasma process may be used to remove the photoresist layer 250. Nevertheless, other types of removal processes could be used to remove the photoresist layer 250. It should be noted that while FIG. 4 illustrates and describes that the etch-stop layer 230 is removed before removal of the photoresist layer 250, other embodiments may exist wherein the opposite order is used.

What often results after removal of the etch-stop layer 230 and/or the photoresist layer 250 is a residue 410 (e.g., polymeric residue) in the cavity 310. The residue 410, as illustrated, may be located above the conductive feature 220. For instance, the residue 410 may be located on the surface of the conductive feature 220 as well as on the sidewalls of the cavity 310. Alternatively, the residue 410 may be located on either one or the other.

The residue 410 illustrated in FIG. 4 contains embedded metal therein. For instance, the residue may contain embedded copper wherein the conductive feature 220 is a copper conductive feature. It is believed that when the etch used to remove the etch-stop layer 230 comes into contact with the conductive feature 220, even for a short period of time, the energy from the etch causes particles from the conductive feature 220 to depart therefrom and enter into the plasma environment. Unfortunately, these metal particles become embedded in the residue 410 that forms above the conductive feature 220.

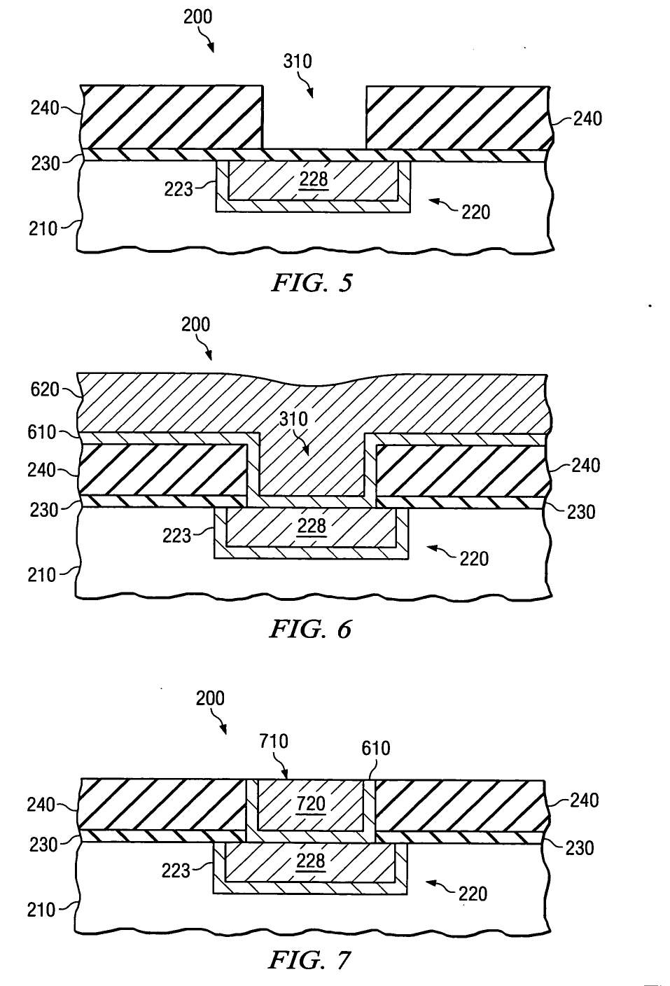

Turning now to FIG. 5, with continued reference to FIG. 1, illustrated is a cross-sectional view of the partially completed interconnect structure 200 illustrated in FIG. 4 after having removed the residue 410 using a unique process conducted in accordance with the principles of the present invention. As previously indicated in the discussion with respect to FIG. 1, the residue 410 may be removed using a multiple step process. In an initial step, similar to the step 150 of FIG. 1, the residue 410 is subjected to a short duration oxidation process so as to oxidize a substantial portion of the embedded metal within the residue 410. It is believed that if the right amount of oxidation occurs to the embedded metal of the residue 410 without causing undue amounts of oxidation to the conductive feature 220, the residue having the oxidized embedded metal may then be removed much more easily. The key, however, is to tailor the oxidation of the embedded metal of the residue 410 such that little to no oxidation of the conductive feature 220 occurs. As those skilled in the art appreciate, substantial oxidation of the conductive feature 220 could cause serious device reliability problems.

Given the foregoing desire to substantially oxidize the embedded metal within the residue 410 without substantially oxidizing the conductive feature 220, various different oxidation processes and parameters could be used. As previously indicated, it has been observed that, among others, the short duration oxidation process may be tailored (e.g., as a whole) such that the residue 410 is subjected to the oxidation process for a period of time of less than about 60 seconds, with a preferred time range of between about 10 seconds and about 45 seconds. As the time and temperature of the short duration oxidation process are somewhat related, a temperature of less than about 100° C., with an exemplary temperature ranging from about room temperature to about 60° C., might be used. Similarly, a pressure ranging from about 5 mTorr to about 2000 mTorr, and a power ranging from about 300 watts to about 1500 watts, might also be used.

Not only may different processing conditions be used to oxidize the embedded metal within the residue 410, different plasma generating tools may also be used. For instance, in one embodiment, a Mattson stand-alone ash tool (e.g., Aspen II platform tool) was used to oxidize the embedded metal within the residue 410. In this embodiment, the Aspen II tool was an inductively coupled plasma asher tool capable of being operated in a selectable mode (ICPsm). The selectable mode allowed the ions, for the most part, to effectively be turned off at the surface of the wafer and instead, be collected using a Faraday shield. In this embodiment, the residue 410 having the embedded material was subjected to substantially pure oxygen gas (O₂) for a period of about 30 seconds at a temperature of about 60° C., which resulted in the appropriate amount of oxidation of the embedded metal of the residue 410 without undue amounts of oxidation to the conductive feature 220.

In another embodiment, however, the residue 410 was subjected to the oxidation process using a Mattson ash tool (e.g., Aspen III platform Highlands (HLDS) tool) having two radio frequency (RF) sources. For example, the Aspen III HLDS tool has both an RF source and an RF bias capability. As the bias, which in this embodiment might range between about zero watts and about 75 watts, is applied to the chuck holding the wafer, the ions formed in the plasma may be bombarded upon the residue 410 with greater energy. Accordingly, more physical interaction occurs between the plasma species and the wafer species. In this embodiment, the residue 410 having the embedded material was subjected to substantially pure oxygen gas (O₂) for a period of about 30 seconds at room temperature using a 30 watt bias, which again resulted in the appropriate amount of oxidation of the embedded metal of the residue 410 without undue amounts of oxidation to the conductive feature 220. Those skilled in the art understand that each of the processing conditions disclosed above may be tailored, without limitation. Accordingly, the present invention should not be limited to the few examples given above.

After subjecting the residue 410 to the short duration oxidation process, of which ideally resulted in the appropriate amount of oxidation of the embedded metal of the residue 410, the residue 410 may be removed using an etch process. While the removing of the residue 410 in this embodiment has been discussed as an etch process, the term etch as used in this removal step includes etching, washing and/or cleaning the partially completed interconnect structure 200 to remove the residue 410.

As previously indicated, in one advantageous embodiment a wet etch, such as a fluorine containing wet etch, could be used to remove the residue 410 having the oxidized embedded metal. In an exemplary embodiment, the wet etch process uses a fluorine-containing solvent, and is conducted for a time period ranging from about 15 seconds to about 600 seconds. Nevertheless, other etches, cleans, solvents conducted for other amounts of time could also be used while remaining within the purview of the present invention.

Turning now to FIG. 6, with continued reference to FIG. 1, illustrated is a cross-sectional view of the partially completed interconnect structure 200 illustrated in FIG. 5 after forming a conventional barrier/adhesion layer within the cavity 310 in the dielectric layer 240, such as the metal barrier/adhesion layer 610, and forming a blanket layer of conductive material 620 over the metal barrier/adhesion layer 610 and within the cavity 310. The metal barrier/adhesion layer 610 may comprise similar types of materials as the barrier/adhesion layer 223, such as Ti, TiN, a Ti/TiN stack, Ta, TaN, a Ta/TaN stack or combinations of these or other useful metal barrier materials. Similarly, the blanket layer of conductive material 620 may comprise similar types of materials as the conductive plug 228. Therefore, in the embodiment of FIG. 6, the metal barrier/adhesion layer 610 comprises a tantalum/tantalum nitride stack and the blanket layer of conductive material 620 comprises copper or copper doped aluminum.

Turning now to FIG. 7, with continued reference to FIG. 1, illustrated is a cross-sectional view of the partially completed interconnect structure 200 illustrated in FIG. 6 after conventionally polishing the blanket layer of conductive material 620 to form a second conductive feature 710. The second conductive feature 710, as those skilled in the art would expect, comprises the metal barrier/adhesion layer 610 and a conductive plug 720. The planarization is preferably accomplished by chemical-mechanical polishing (CMP) or a blanket etch-back process. The portions of the metal barrier/adhesion layer 610 located above the dielectric layer 240 are generally removed, as shown in FIG. 7. Further processing can be performed using standard device processing techniques, which would be obvious to one of ordinary skill in the art.

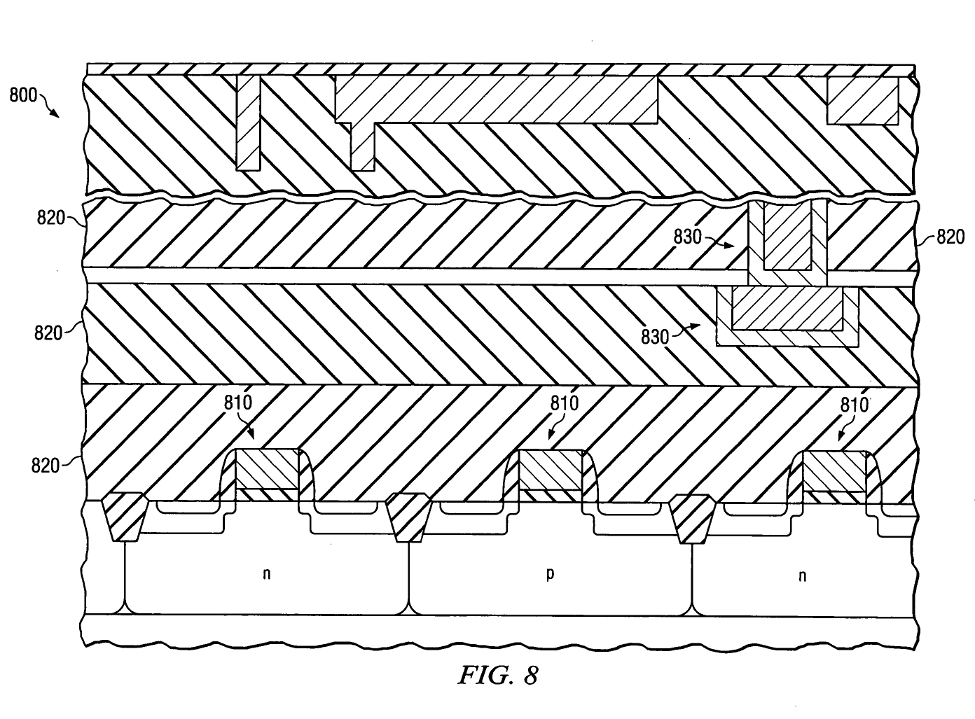

Referring now to FIG. 8, illustrated is an exemplary cross-sectional view of an integrated circuit (IC) 800 incorporating interconnect structures 830 constructed according to the principles of the present invention. The IC 800 may include devices, such as transistors used to form CMOS devices, BiCMOS devices, Bipolar devices, as well as capacitors or other types of devices. The IC 800 may further include passive devices, such as inductors or resistors, or it may also include optical devices or optoelectronic devices. Those skilled in the art are familiar with these various types of devices and their manufacture. In the particular embodiment illustrated in FIG. 8, the IC 800 includes transistor devices 810 having dielectric layers 820 located thereover. Additionally, interconnect structures 830 are located within the dielectric layers 820 to interconnect various devices, thus, forming the operational integrated circuit 800.

Although the present invention has been described in detail, those skilled in the art should understand that they can make various changes, substitutions and alterations herein without departing from the spirit and scope of the invention in its broadest form.

What is claimed is:

1. A method for removing residue from a cavity during the formation of an interconnect structure, comprising:
subjecting residue having an embedded metal therein located within a cavity in a dielectric layer and over at least a portion of a conductive feature to a short duration oxidation process so as to oxidize a substantial portion of the embedded metal; and
removing the residue containing the oxidized embedded metal using an etch process.

2. The method as recited in claim 1 wherein the subjecting includes subjecting residue for a period of time of less than about 60 seconds.

3. The method as recited in claim 1 wherein the subjecting includes subjecting residue using a temperature of less than about 100° C.

4. The method as recited in claim 1 wherein the subjecting includes subjecting residue using a pressure ranging from about 5 mTorr to about 2000 mTorr.

5. The method as recited in claim 1 wherein the subjecting includes subjecting residue using a power ranging from about 300 watts to about 1500 watts.

6. The method as recited in claim 1 wherein the subjecting includes subjecting using an oxygen containing fluid.

7. The method as recited in claim 6 wherein the oxygen containing fluid is commercially pure oxygen gas.

8. The method as recited in claim 1 wherein the subjecting includes subjecting using a biased plasma source.

9. The method as recited in claim 1 wherein the removing includes removing the residue having the oxidized embedded metal using a fluorine containing wet etch.

10. A method for creating an interconnect structure, comprising:
forming a cavity in a dielectric layer located over a substrate to expose a portion of an etch-stop layer underlying the dielectric layer;
removing the exposed portion of the etch-stop layer to expose at least a portion of a conductive feature underlying the etch-stop layer, the removing leaving a residue having an embedded metal therein above at least a portion of the conductive feature;
subjecting the residue having the embedded metal therein to a short duration oxidation process so as to oxidize a substantial portion of the embedded metal; and
removing the residue containing the oxidized embedded metal using an etch process.

11. The method as recited in claim 10 wherein the subjecting includes subjecting residue for a period of time of less than about 60 seconds.

12. The method as recited in claim 10 wherein the subjecting includes subjecting residue using a temperature of less than about 100° C.

13. The method as recited in claim 10 wherein the subjecting includes subjecting residue using a pressure ranging from about 5 mTorr to about 2000 mTorr.

14. The method as recited in claim 10 wherein the subjecting includes subjecting residue using a power ranging from about 300 watts to about 1500 watts.

15. The method as recited in claim 10 wherein the subjecting includes subjecting using an oxygen containing fluid.

16. The method as recited in claim 15 wherein the oxygen containing fluid is commercially pure oxygen gas.

17. The method as recited in claim 10 wherein the subjecting includes subjecting using a biased plasma source.

18. The method as recited in claim 10 wherein the removing includes removing the residue having the oxidized embedded metal using a fluorine containing wet etch.

19. The method as recited in claim 10 further including filling the cavity having the residue removed therefrom with a conductive material.

20. A method for manufacturing an integrated circuit, comprising:
providing a semiconductor substrate having transistor devices located thereover;
forming a dielectric layer over the transistor devices; and
forming an interconnect structure within the dielectric layer, the interconnect structure contacting at least one of the transistor devices, including;
forming a cavity in the dielectric layer to expose a portion of an etch-stop layer underlying the dielectric layer;
removing the exposed portion of the etch-stop layer to expose at least a portion of a conductive feature underlying the etch-stop layer, the removing leaving a residue having an embedded metal therein above at least a portion of the conductive feature;
subjecting the residue having the embedded metal therein to a short duration oxidation process so as to oxidize a substantial portion of the embedded metal;
removing the residue containing the oxidized embedded metal using an etch process; and
filling the cavity having the residue removed therefrom with a conductive material.

21. The method as recited in claim 20 wherein the subjecting includes subjecting residue for a period of time of less than about 60 seconds.

22. The method as recited in claim 20 wherein the subjecting includes subjecting residue using a temperature of less than about 100° C.

23. The method as recited in claim 20 wherein the subjecting includes subjecting residue using a pressure ranging from about 5 mTorr to about 2000 mTorr.

24. The method as recited in claim 20 wherein the subjecting includes subjecting residue using a power ranging from about 300 watts to about 1500 watts.

25. The method as recited in claim 20 wherein the subjecting includes subjecting using an oxygen containing fluid.

26. The method as recited in claim 25 wherein the oxygen containing fluid is commercially pure oxygen gas.

27. The method as recited in claim 20 wherein the subjecting includes subjecting using a biased plasma source.

28. The method as recited in claim 20 wherein the removing includes removing the residue having the oxidized embedded metal using a fluorine containing wet etch.
